(19) United States
(12) Patent Application Publication
(10) Pub. No.: US 2024/0094465 A1
(43) Pub. Date: Mar. 21, 2024

(54) PHOTONIC INTEGRATED CIRCUIT INCLUDING PLURALITY OF DISCRETE OPTICAL GUARD ELEMENTS

(71) Applicant: GlobalFoundries U.S. Inc., Malta, NY (US)

(72) Inventors: Yusheng Bian, Ballston Lake, NY (US); Mark D. Levy, Williston, VT (US); Siva P. Adusumilli, South Burlington, VT (US); Karen A. Nummy, Newburgh, NY (US); Zhuojie Wu, Port Chester, NY (US); Ramsey Hazbun, Colchester, VT (US)

(21) Appl. No.: 17/932,868

(22) Filed: Sep. 16, 2022

(51) Int. Cl. G02B 6/122; G02B 6/13

(52) U.S. Cl. CPC G02B 6/1228; G02B 6/13

(57) ABSTRACT

The disclosure relates to a PIC structure including a photonic component on a semiconductor substrate. Each of a plurality of optical guard elements are composed of a light absorbing material and are in proximity to the photonic component. The optical guard elements may mimic an outer periphery of at least a portion of the photonic component. The optical guard elements may include at least one of: a germanium body positioned at least partially in a silicon element, a silicon body having a high dopant concentration, and a polysilicon body having a high dopant concentration over the silicon body.

### BACKGROUND

The present disclosure relates to semiconductor structures and, more particularly, to a photonic integrated circuit including a plurality of discrete optical guard elements for a photonic component and methods of manufacture.

Photonic integrated circuits (PICs) can be made using existing semiconductor fabrication techniques, and because silicon is already used as the substrate for most integrated circuits, it is possible to create hybrid devices in which the optical and electronic components are integrated onto a single microchip. PICs include a variety of photonic components that receive and/or output optical signals. Certain optical components in a PIC, such as optical input/output couplers, laser couplers, among others, can create stray optical signals. The stray optical signals are scattered through the PIC structure and create background optical noise. The stray optical signals received by an unintended photonic component, e.g., a photodetector, may create operational problems for that component.

### SUMMARY

All aspects, examples and features mentioned below can be combined in any technically possible way.

An aspect of the disclosure provides a photonic integrated circuit (PIC) structure, comprising: a photonic component on a semiconductor substrate; and a plurality of discrete optical guard elements each composed of a light absorbing material and in proximity to the photonic component.

An aspect of the disclosure includes a photonic integrated circuit (PIC) structure, comprising: a photonic component on a semiconductor substrate; and a plurality of discrete optical guard elements composed of a light absorbing material and in proximity to the photonic component, wherein the plurality of discrete optical guard elements each include a metamaterial including at least one of silicon and germanium, and wherein the plurality of discrete optical guard elements are arranged in a manner to mimic an outer periphery of at least a portion of the photonic component.

An aspect of the disclosure includes a method, comprising: forming a photonic component on a semiconductor substrate; and forming a plurality of discrete optical guard elements composed of a light absorbing material and in proximity to the photonic component.

Two or more aspects described in this disclosure, including those described in this summary section, may be combined to form implementations not specifically described herein.

The details of one or more implementations are set forth in the accompanying drawings and the description below. Other features, objects and advantages will be apparent from the description and drawings, and from the claims.

### BRIEF DESCRIPTION OF THE DRAWINGS

The embodiments of this disclosure will be described in detail, with reference to the following figures, wherein like designations denote like elements, and wherein:

FIG. 1 shows a schematic top-down view of a PIC structure, according to embodiments of the disclosure.

FIG. 2 shows a cross-sectional view of a PIC structure along view line A-A in FIG. 1, according to embodiments of the disclosure.

FIG. 3 shows a schematic top-down view of a PIC structure, according to other embodiments of the disclosure.

FIG. 4 shows a cross-sectional view of a PIC structure along view line B-B in FIG. 3, according to other embodiments of the disclosure.

FIG. 5 shows a schematic top-down view of a PIC structure, according to other embodiments of the disclosure.

FIG. 6 shows a cross-sectional view of a PIC structure along view line C-C in FIG. 5, according to other embodiments of the disclosure.

FIG. 7 shows a cross-sectional view of a PIC structure, according to yet other embodiments of the disclosure.

FIG. 8 shows a schematic top-down view of a PIC structure, according to other embodiments of the disclosure.

FIG. 9A-H show schematic top-down views of discrete optical guard element shapes, according to various embodiments of the disclosure.

FIG. 10 shows a schematic top-down view of a PIC structure, according to other embodiments of the disclosure.

FIG. 11 shows a schematic top-down view of a PIC structure, according to other embodiments of the disclosure.

FIG. 12 shows a schematic top-down view of a PIC structure, according to other embodiments of the disclosure.

FIG. 13 shows a schematic top-down view of a PIC structure, according to other embodiments of the disclosure.

FIG. 14 shows a schematic top-down view of a PIC structure, according to other embodiments of the disclosure.

FIG. 15 shows a cross-sectional view of a PIC structure along view line D-D in FIG. 14, according to other embodiments of the disclosure.

FIG. 16 shows a schematic top-down view of a PIC structure, according to other embodiments of the disclosure.

FIG. 17 shows a cross-sectional view of a PIC structure along view line E-E in FIG. 16, according to other embodiments of the disclosure.

FIG. 18 shows a schematic top-down view of a PIC structure, according to other embodiments of the disclosure.

FIG. 19 shows a cross-sectional view of a PIC structure along view line F-F in FIG. 18, according to other embodiments of the disclosure.

FIG. 20 shows a schematic top-down view of a PIC structure, according to other embodiments of the disclosure.

FIG. 21 shows a cross-sectional view of a PIC structure along view line G-G in FIG. 20 according to other embodiments of the disclosure.

FIG. 22 shows a cross-sectional view of a PIC structure, according to other embodiments of the disclosure.

FIG. 23 shows a cross-sectional view of a PIC structure, according to other embodiments of the disclosure.

It is noted that the drawings of the disclosure are not necessarily to scale. The drawings are intended to depict only typical aspects of the disclosure, and therefore should not be considered as limiting the scope of the disclosure. In the drawings, like numbering represents like elements between the drawings.

### DETAILED DESCRIPTION

In the following description, reference is made to the accompanying drawings that form a part thereof, and in which is shown by way of illustration specific illustrative embodiments in which the present teachings may be practiced. These embodiments are described in sufficient detail to enable those skilled in the art to practice the present teachings, and it is to be understood that other embodiments may be used and that changes may be made without departing from the scope of the present teachings. The following description is, therefore, merely illustrative.

It will be understood that when an element such as a layer, region, or substrate is referred to as being “on” or “over” another element, it may be directly on the other element or intervening elements may also be present. In contrast, when an element is referred to as being “directly on” or “directly over” another element, there may be no intervening elements present. It will also be understood that when an element is referred to as being “connected” or “coupled” to another element, it may be directly connected or coupled to the other element or intervening elements may be present. In contrast, when an element is referred to as being “directly connected” or “directly coupled” to another element, there are no intervening elements present.

Reference in the specification to “one embodiment” or “an embodiment” of the present disclosure, as well as other variations thereof, means that a particular feature, structure, characteristic, and so forth described in connection with the embodiment is included in at least one embodiment of the present disclosure. Thus, the phrases “in one embodiment” or “in an embodiment,” as well as any other variations appearing in various places throughout the specification are not necessarily all referring to the same embodiment. It is to be appreciated that the use of any of the following “/,” “and/or,” and “at least one of,” for example, in the cases of “A/B,” “A and/or B” and “at least one of A and B,” is intended to encompass the selection of the first listed option (a) only, or the selection of the second listed option (B) only, or the selection of both options (A and B). As a further example, in the cases of “A, B, and/or C” and “at least one of A, B, and C,” such phrasing is intended to encompass the first listed option (A) only, or the selection of the second listed option (B) only, or the selection of the third listed option (C) only, or the selection of the first and the second listed options (A and B), or the selection of the first and third listed options (A and C) only, or the selection of the second and third listed options (B and C) only, or the selection of all three options (A and B and C). This may be extended, as readily apparent by one of ordinary skill in the art, for as many items listed.

Embodiments of the disclosure relate to a PIC structure including a photonic component on a semiconductor substrate. A plurality of optical guard elements are each in proximity to the photonic component. The plurality of optical guard elements may include at least one of: a germanium body positioned at least partially in a silicon element, a silicon body having a high dopant concentration, and a polysilicon body having a high dopant concentration over the silicon body. The plurality of optical guard elements reduces optical noise and improve performance for functional components and circuits (e.g., dark current reduction, scattering loss reduction). The optical guard elements are fully compatible with current semiconductor process flows and may not require additional layers and/or process steps. The optical guard elements can be placed in any area where stray optical signals (light scattering) are anticipated, such as but not limited to in proximity to optical input/outputs such as an edge coupler, laser cavity/coupler, V-groove and input/out for single mode fiber (IOSMF), grating coupler, or chip edges; in proximity to waveguide bends, couplers, splitters, spiral absorbers, etc.; and/or surrounding sensitive photonic components such as photodetectors and/or optical modulators. The optical guard elements can have any horizontal cross-sectional shape or size and can be arranged in any manner to block unwanted optical signals.

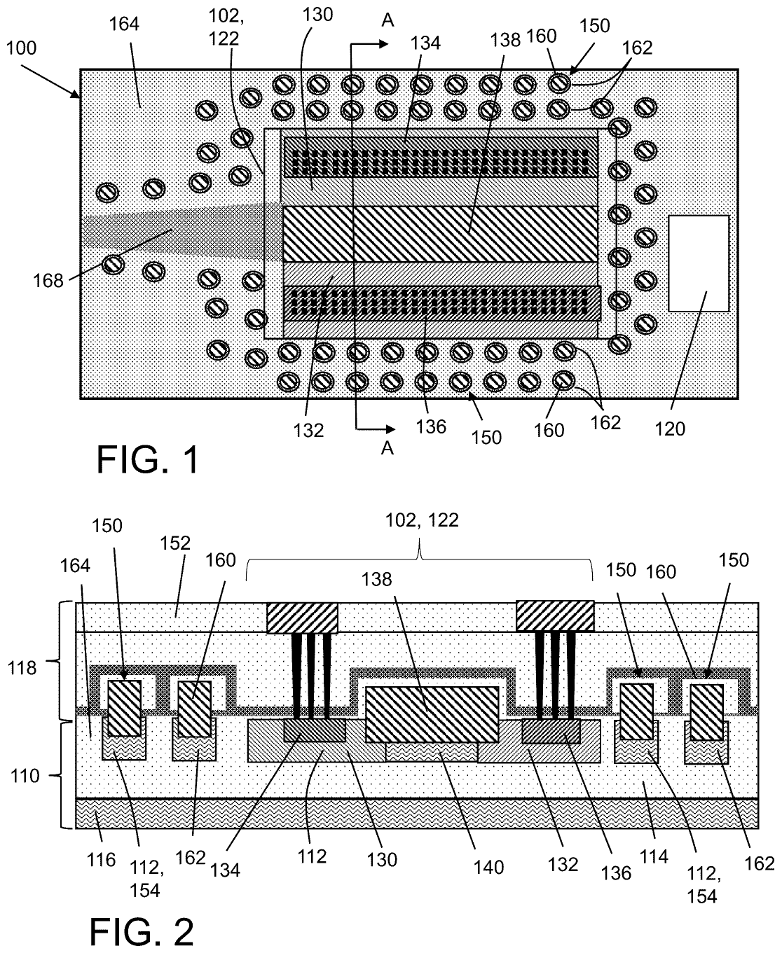

FIG. 1 shows a schematic top-down view and FIG. 2 shows a cross-sectional view of a PIC structure 100 along view line A-A in FIG. 1, according to embodiments of the disclosure. PIC structure 100 includes a photonic component 102 on a semiconductor substrate 110. More specifically, PIC structure 100 includes semiconductor substrate 110, which may include any now known or later developed semiconductor substrate. In the non-limiting example shown, semiconductor substrate 110 includes a layered semiconductor-insulator-semiconductor substrate in place of a more conventional silicon substrate (bulk substrate). As shown in FIG. 2, semiconductor substrate 110 includes a semiconductor-on-insulator (SOI) layer 112 over a buried insulator layer 114 over a base semiconductor layer 116. SOI layer 112 and base semiconductor layer 116 may include but are not limited to: silicon, germanium, silicon germanium, silicon carbide. Buried insulator layer 114 may include any appropriate dielectric such as but not limited to silicon dioxide, i.e., forming a buried oxide (BOX) layer. A portion of or the entire semiconductor substrate may be strained. The precise thickness of buried insulating layer 114 and SOI layer 112 may vary widely with the intended application. Although shown in an SOI format, the teachings of the disclosure are applicable to any PIC substrate format, e.g., a bulk semiconductor substrate.

An electronic component 120 (FIG. 1 only for clarity) may be formed, for example, in an active region of SOI layer 112, e.g., at a location other than where photonic component 102 is located. Photonic component 102 may be operatively connected and interact with electric component 120 in any now known or later developed fashion. In certain embodiments, photonic component 102 may be positioned in SOI layer 112. In other embodiments, photonic component 102 may be in any layer of a dielectric stack of materials 118 over semiconductor substrate 110. In embodiments, electronic component 120 may be any passive or active device including, e.g., transistors with contacts and metal wiring layers, etc.

Photonic component 102 may be any optical component such as but not limited to at least one of: a photodetector, an avalanche photodiode (APD), an optical waveguide, an optical input/output coupler, and an optical absorber. Photonic component 102 is optically coupled through some sort of optical signal guiding structure, such as an optical waveguide 168, within PIC structure 100 to receive the desired optical signals. The optical signals typically, but not necessarily, travel in a plane of semiconductor substrate 110. Optical signals entering from outside of the optical signal guiding structure are considered undesired or harmful ‘stray optical signals’ or ‘optical noise.’

For description purposes, as shown in, for example, FIGS. 1-7, photonic component 102 is mostly illustrated as some sort of photodetector 122. In other drawings, photonic component 102 is illustrated in a more generic form for ease of illustration. For purposes of illustration, photodetector 122, as shown in FIGS. 1-2, includes a PN photodetector including a N+ region 130 and a P+ region 132 in SOI layer 112. An N++ region 134 is positioned in N+ region 130 and a P++ region 136 is positioned in P+ region 132. Any number of contacts (black vertical lines) may land on N++ region 134 and P++ region 136 for electric coupling to, for example, a first metal layer 152. Photodetector 122 also includes an (intrinsic) germanium region 138 coupling N+ region 130 and P+ region 132. An undoped region 140 (FIGS. 2, 4, 6, and 7) of SOI layer 112 may separate N+ region 130 and P+ region 132. In FIG. 4, photodetector 122 is in the form of an avalanche photodiode, which also includes a charge region 142 in undoped region 140 of SOI layer 112 and in contact with germanium region 138.

PIC structure 100 also includes a plurality of optical guard elements 150 composed of a light absorbing material and in proximity to photonic component 102. While one photonic component 102 is shown in each drawing, photonic component 102 may be one of a plurality of photonic components 102 over or on semiconductor substrate 110, and plurality of optical guard elements 150 (hereafter “guard elements 150” for brevity) may be in proximity to any number of photonic components 102. More particularly, guard elements 150 may be applied to any desired one or more photonic components 102 for which stray optical signals are a concern. Hence, guard elements 150 may protect a single photonic component 102 amongst a plurality of photonic components in PIC structure 100, or it may protect more than one optical component 102.

As used herein, “in proximity to” indicates guard elements 150 are in position to absorb the relevant stray optical signals, e.g., light or other radiation, that may affect operation of desired photonic component(s) 102 by being either adjacent to or substantially surround the desired photonic component(s) 102. As used herein, “substantially surround” indicates photonic component(s) 102 is/are generally surrounded except where gaps exist between guard elements 150 or some sort or lateral optical communication structure is present, e.g., optical waveguide 168. As shown in FIG. 1, in certain embodiments, guard elements 150 may be arranged in a manner to approximate or mimic the shape of an outer periphery 166 of at least a portion of photonic component 102. In the example shown in FIG. 1, guard elements 150 are arranged in a rectangular form to mimic the rectangular nature of the outer periphery of photonic component 102. Other arrangements are possible depending on the shape of photonic component 102.

As shown in FIG. 2, in certain embodiments, guard elements 150 may include at least a portion thereof positioned in an active semiconductor layer 154. In FIG. 2, guard elements 150 may also be entirely below a first metal layer 152. Active semiconductor layer 154 is part of SOI layer 112 and includes active portions of electric components 120 formed therein, e.g., source/drain regions of transistors. As will be further described, guard elements 150 prevent stray optical signals from reaching photonic component(s) 102. Guard elements 150 may also be combined with other guard or security structures, such as BEOL interconnect layers, thereover to further prevent stray optical signals from reaching the desired photonic component(s) 102.

Guard elements 150 each include a metamaterial including at least one of silicon and germanium. In FIGS. 1-4, guard elements 150 may include a germanium body 160 positioned at least partially in a silicon element 162. Germanium body 160 may include monocrystalline (epitaxially grown) or polycrystalline germanium. In certain embodiments, silicon element 162 is positioned in active semiconductor layer 154 (e.g., SOI layer 112) which, as noted, may include doped regions for active portions of electric component 120, but which may be undoped for guard elements 150. In other embodiments, silicon element 162 may be formed in any layer of PIC structure 100, e.g., in dielectric stack of materials 118. Where guard elements 150 are partially in active semiconductor layer 154, germanium body 160 may be formed at the same time as germanium region 138 of photodetector 122.

In FIGS. 1-2, guard elements 150 include any number of elements positioned along sides of photonic component 102. Guard elements 150 can be arranged in any manner to provide the desired optical signal blocking. Optical waveguide 168, optionally, may extend through a gap in guard elements 150, and may be in optical communication with photonic component 102. Optical waveguide 168 may include any now known or later developed waveguide structure(s), e.g., silicon or silicon nitride. Optical waveguide 168 laterally directs operative optical signals to photonic component 102. In this embodiment, guard elements 150 are generally in one or more rows alongside photonic component 102 and are surrounded by a dielectric layer 164, e.g., an inter-layer dielectric material such as an oxide. In certain embodiments, as shown in FIGS. 1 and 2, guard elements 150 are arranged in at least two rows, e.g., alongside photonic component 102. In FIG. 1, guard elements 150 are mostly equidistantly spaced, i.e., they are periodically spaced. That is, guard elements 150 are uniformly spaced along an outer periphery of at least a portion of photonic component 102. Some variation due to fabrication limitations may be present.

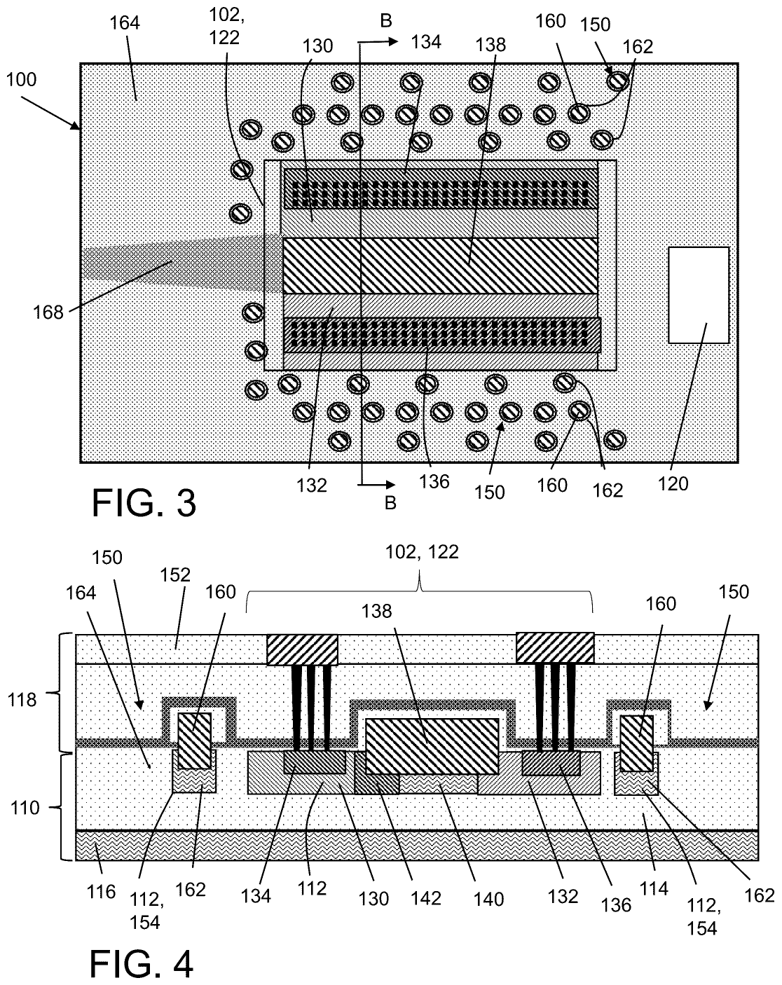

FIG. 3 shows a schematic top-down view and FIG. 4 shows a cross-sectional view of a PIC structure 100 along view line B-B in FIG. 3, according to embodiments of the disclosure. FIG. 3 shows a different arrangement of guard elements 150 compared to FIG. 1. In FIG. 3, more rows (3) are used in some areas but with a lower number of guard elements 150, and less or no rows of guard elements 150 are used in other areas compared to FIG. 1. In contrast to FIG. 1, in FIG. 3, guard elements 150 are not equidistantly spaced, i.e., the spacing varies. That is, guard elements 150 are non-uniformly spaced along an outer periphery of at least a portion of photonic component 102, i.e., they are not periodically spaced. Uniform spacing and non-uniform spacing of guard elements 150 for different portions of photonic component 102 may be used also.

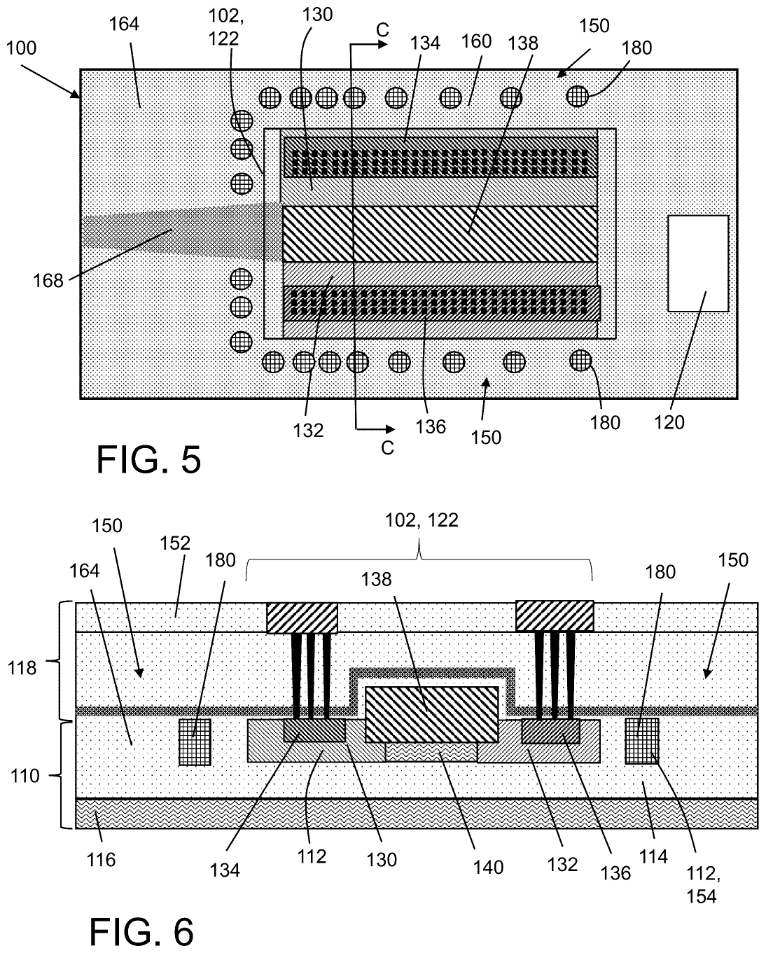

FIG. 5 shows a schematic top-down view and FIG. 6 shows a cross-sectional view of PIC structure 100 along view line C-C in FIG. 5, according to embodiments of the disclosure. Referring to FIGS. 5 and 6, in other embodiments, guard elements 150 may include a silicon body 180. In certain embodiments, silicon body 180 may be positioned in active semiconductor layer 154, i.e., all layer 112, which may include doped regions for active portions of electric component 120 (not shown), but which is differently doped for guard elements 150. In other embodiments, silicon body 180 may be formed in any layer of PIC structure 100, e.g., in dielectric stack of materials 118. In any event, silicon body 180 has a high dopant concentration of, for example, boron, phosphorous, arsenic, indium, and/or antimony. Such doping creates free carriers (electrons/holes in conduction band/valence band) which absorb light. Alternatively, silicon can also be doped with lower band gap material such as germanium (0.66 eV band gap) so that it will absorb infrared light used in photonics applications. Regarding silicon body 180, “high dopant concentration” indicates silicon body 180 has dopant concentration of greater than 1×10¹⁸ per cubic centimeter (cm³). Here, silicon body 180 can be formed during the same processes of other active regions, e.g., for source/drain regions of electric components 120 (FIG. 1) in the form of transistors, in active semiconductor layer 154. Also, in contrast to FIG. 1, guard elements 150 are not equidistantly spaced in FIG. 5, i.e., the spacing varies. It will be recognized that guard elements 150 in the form of silicon bodies 180 can be uniformly spaced, if desired.

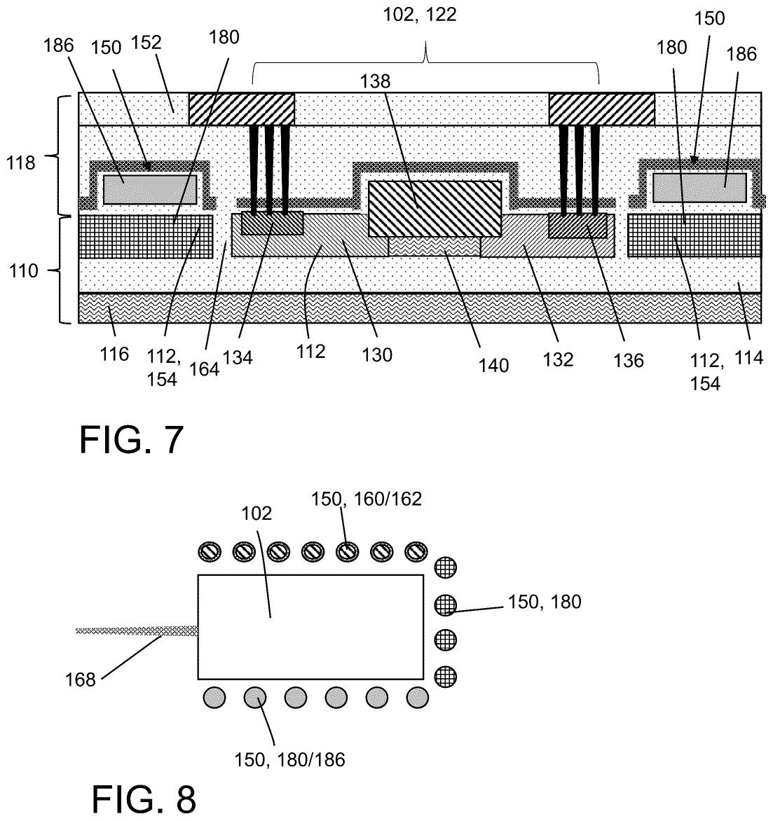

Referring to FIG. 7, in another embodiment, guard elements 150 may further include a polysilicon body 186 having a high dopant concentration over silicon body 180. In certain embodiments, polysilicon body 186 with silicon body 180 may be positioned in active semiconductor layer 154, i.e., SOI layer 112. Active semiconductor layer 154 may include doped regions for active portions of electric component 120 (not shown), but is differently doped for guard elements 150 with silicon body 180 and polysilicon body 186. In other embodiments, silicon body 180 and polysilicon body 186 may be formed in any layer of PIC structure 100, e.g., in dielectric stack of materials 118. In any event, polysilicon body 186 has a high dopant concentration. Regarding polysilicon body 186, “high dopant concentration” indicates polysilicon body 186 has a dopant concentration of greater than 1×10¹⁸ per cubic centimeter (cm³). The dopants may include boron, phosphorous, arsenic, indium, antimony, and/or germanium. Here, polysilicon body 186 can be formed during the same processes as other polysilicon regions, e.g., for gate regions of electric components 120 (FIG. 1) in the form of transistors, in active semiconductor layer 154. Guard elements 150 in FIG. 7 can be uniformly and/or non-uniformly spaced.

In FIGS. 1-7, guard elements 150 are illustrated as all having the same configuration for a given photonic component 102, e.g., germanium body 160 positioned at least partially in silicon element 162 (FIGS. 1-4), silicon body 180 (FIGS. 5-6) or polysilicon body 186 over silicon body 180. In another embodiment, as shown schematically in FIG. 8, guard elements 150 may include more than one of the above-described embodiments. That is, guard elements 150 may include at least one of: germanium body 160 at least partially in silicon element 162, e.g., in active semiconductor layer 154; silicon body 180, e.g., in active semiconductor layer 154, having a high dopant concentration; and polysilicon body 186 having a high dopant concentration over silicon body 180. Any combination of the embodiments can be used for a particular photonic component 102 and/or a particular PIC structure 100. While particular material arrangements have been described, other light absorbing materials may also be used.

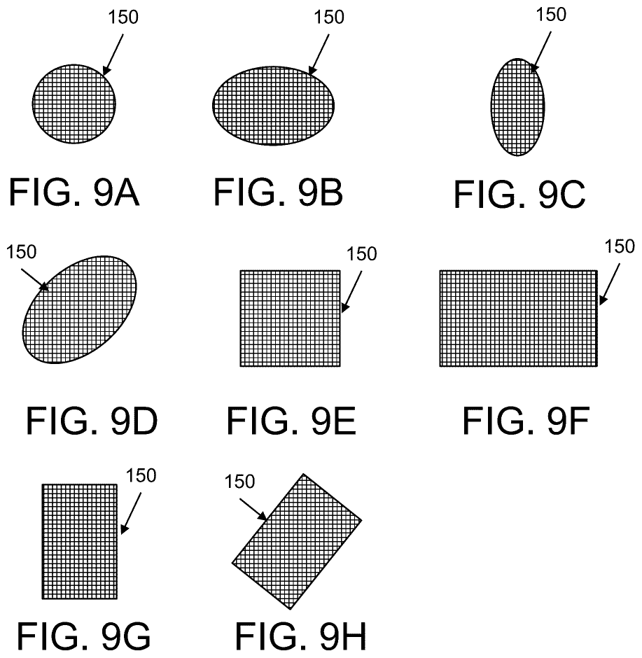

In FIGS. 1-7, guard elements 150 are illustrated as all having the same horizontal cross-sectional shape, e.g., circular, and same vertical size for a given photonic component 102. Guard elements 150 can be customized to absorb any desired amount of stray optical signals by changing their shape and size. As shown in FIGS. 9A-9H, guard elements 150 may each have a horizontal cross-sectional shape that is one of: circular, oval, rectangular, and square. Guard elements 150 can be sized horizontally or vertically as required to obtain the desired optical guarding. In FIGS. 1-7, dielectric layer 164 is provided between guard elements 150 and photonic component 102; however, one or more guard elements 150 can contact photonic component 102, if desired.

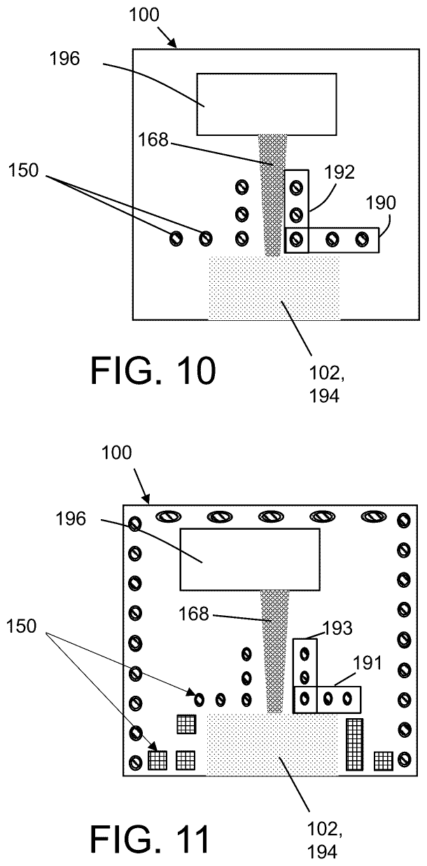

FIG. 10 shows a schematic top-down view of another embodiment of the disclosure. In FIG. 10, guard elements 150 have an L-shape arrangement having a first plurality 190 of guard elements 150 adjacent a portion of photonic component 102 and a second plurality 192 of guard elements 150 adjacent optical waveguide 168 in optical communication with photonic component 102. Some guard elements 150 may be shared amongst the pluralities. (Note, guard elements designated as being in a respective plurality may be chosen arbitrarily and/or not based on physical positions.) Here, a region of concern for optical scatter may be the joint between photonic component 102 in the form of an edge coupler 194, e.g., a V-groove, laser cavity, IOSMF spot size converter, etc., and optical waveguide 168. Optical waveguide 168 may direct optical signals to any variety of other functional components 196, e.g., other electric or photonic components. Guard elements 150 prevent stray optical signals from impacting operation.

FIG. 11 shows a schematic top-down view of another embodiment of the disclosure. In FIG. 11, guard elements 150 have an L-shape having first leg 191 adjacent a portion of an edge coupler 194 (photonic component 102), and second leg 193 adjacent optical waveguide 168 in optical communication with photonic component 102 and other functional components 196, e.g., other electric or photonic components. Here, guard elements 150 also extends around an entire periphery of PIC structure 100. While a single row of guard elements 150 are shown, any number of rows may be used. FIG. 11 also shows an example in which guard elements 150 for a particular photonic component 102 have more than one horizontal cross-sectional shape. In FIG. 11, oval, circular, square and rectangular shapes are all used. Any combination of shapes are possible.

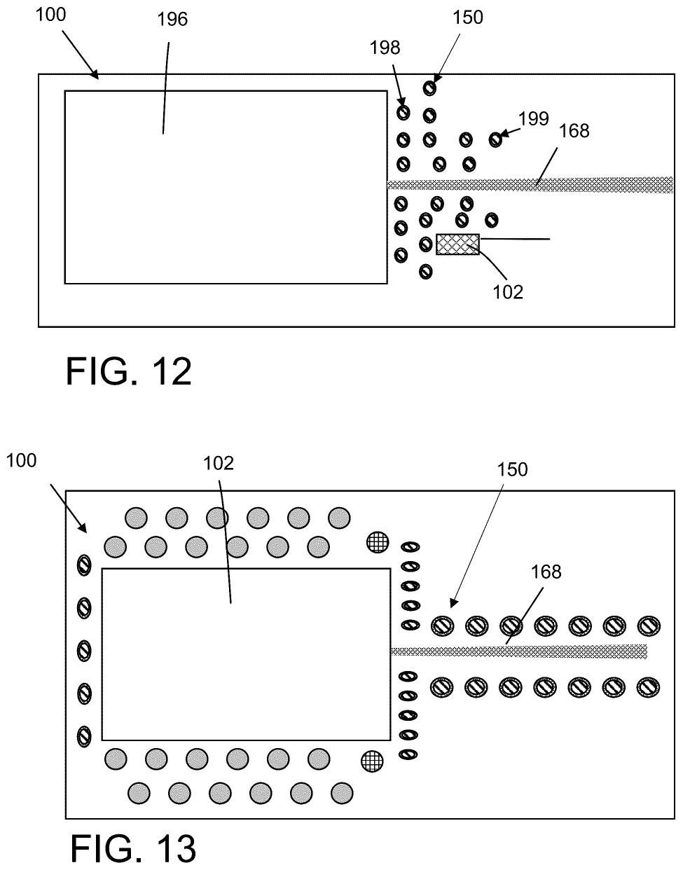

FIG. 12 shows a schematic top-down view of another embodiment of the disclosure. In FIG. 12, guard elements 150 include at least a pair of spaced rows 198, 199, each including the light absorbing material. While shown as L-shaped rows in FIG. 12, any configuration of spaced optical guard elements 150 is possible. In this example, photonic component 102 may include, for example, a cavity with laser attach. Other functional components 196, e.g., other electric or photonic components, may be on the other side of guard elements 150.

FIG. 13 shows a schematic top-down view of another embodiment of the disclosure. In FIG. 13, a single photonic component 102, e.g., a cavity for laser attach, is protected by guard elements 150 that are arranged to surround an outer periphery of photonic component 102 and parts of optical waveguide 168. Guard elements 150 can have any lateral configuration, any horizontal cross-sectional shape, and any horizontal or vertical size.

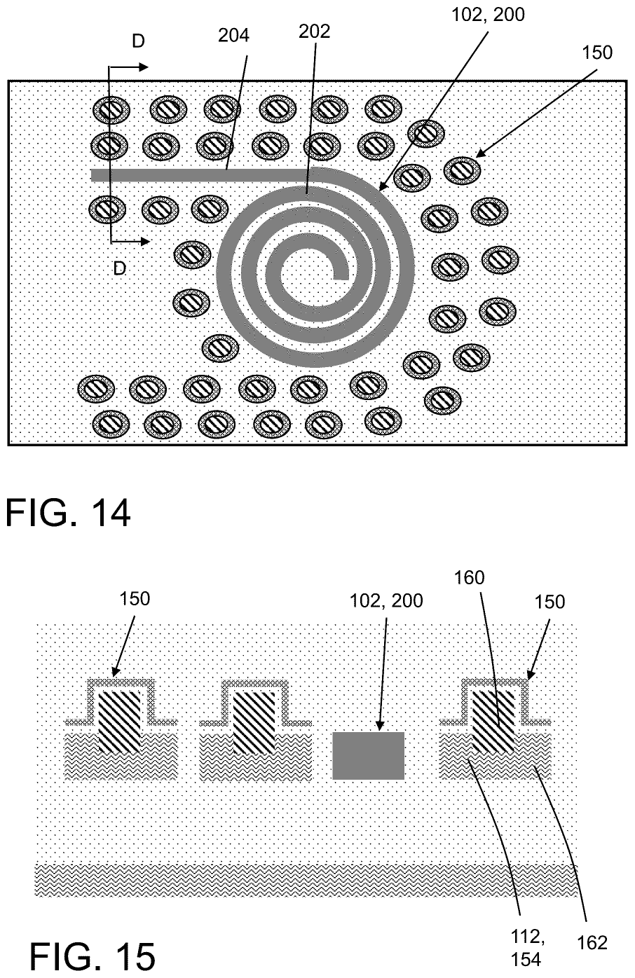

FIG. 14 shows a schematic top-down view and FIG. 15 shows a cross-sectional view along view line D-D in FIG. 14 of another embodiment of the disclosure. In FIGS. 14-15, photonic component 102 includes an optical absorber 200 including a spiral waveguide body 202 and a linear input waveguide 204 coupled to spiral waveguide body 202. Here, guard elements 150 surround spiral waveguide body 202 and linear input waveguide 204 and prevent radiation of optical signals in all directions. Guard elements 150 may absorb optical stray signals resulting in, for example, 50% reduction in optical noise in these embodiments. As shown in FIG. 15, optical absorber 200 includes silicon and may be located in active semiconductor layer 154, e.g., SOI layer 112, with silicon element 162 of guard elements 150; however, this is not necessary in all cases. While FIGS. 14-15 are shown with a germanium body 160 and silicon element 162 embodiment of guard elements 150, the teachings are equally applicable to the other embodiments of FIGS. 5-7.

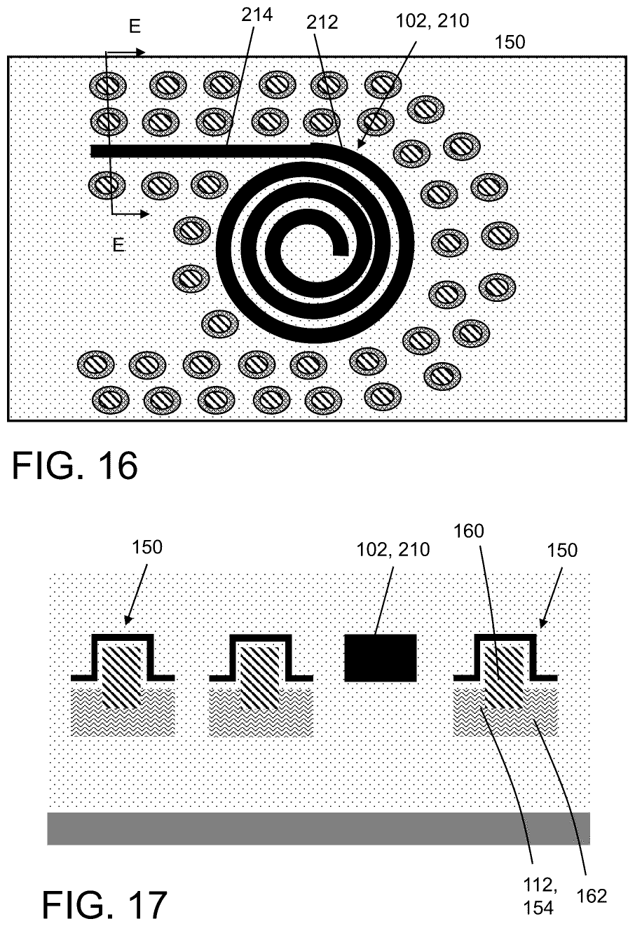

FIG. 16 shows a schematic top-down view and FIG. 17 shows a cross-sectional view along view line E-E in FIG. 15 of another embodiment of the disclosure. In FIGS. 16-17, photonic component 102 includes an optical absorber 210 including a spiral waveguide body 212 and a linear input waveguide 214 coupled to spiral waveguide body 212. Here, guard elements 150 surround spiral waveguide body 212 and linear input waveguide 214 and prevent radiation of optical signals in all directions. Guard elements 150 may absorb optical stray signals resulting in, for example, 50% reduction in optical noise in these embodiments. As shown in FIG. 17, optical absorber 210 may include silicon nitride and may be located above active semiconductor layer 154. While FIGS. 16-17 are shown with a germanium body 160 and silicon element 162 embodiment, the teachings are equally applicable to the other embodiments of FIGS. 5-7.

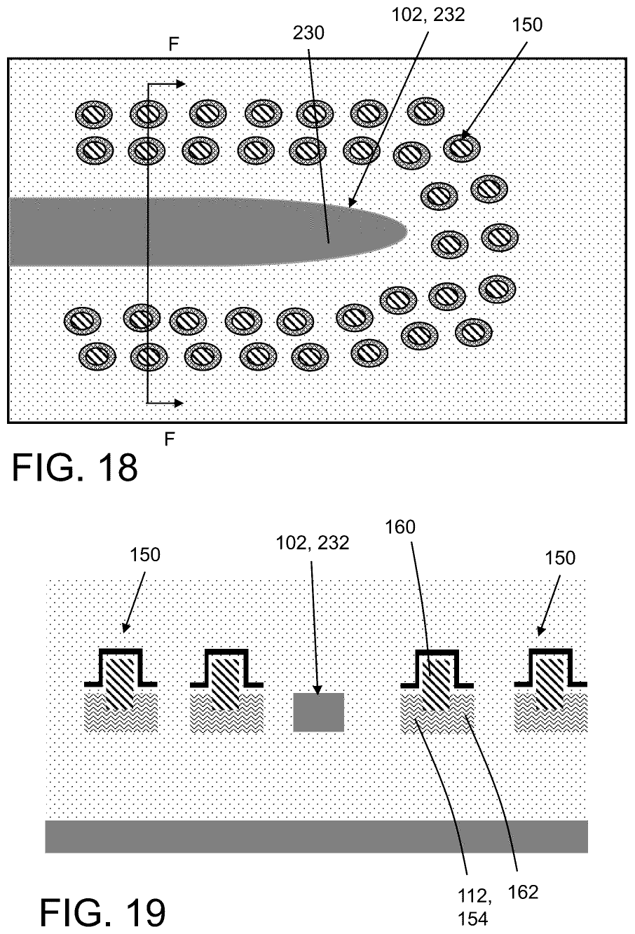

FIG. 18 shows a schematic top-down view and FIG. 19 shows a cross-sectional view along view line F-F in FIG. 18 of another embodiment of the disclosure. FIGS. 18-19 show an embodiment in which photonic component 102 includes a tapered end 230 of a waveguide 232, and guard elements 150 surround tapered end 230 in a U-shaped configuration. Here, guard elements 150 surround tapered end 230 and prevent radiation of optical signals in all directions. As shown in FIG. 19, waveguide 232 includes silicon and may be located in active semiconductor layer 154, e.g., SOI layer 112, with silicon element 162 of guard elements 150; however, this is not necessary in all cases. While FIGS. 18-19 are shown with germanium body 160 and silicon element 162 embodiment of guard elements 150, the teachings are equally applicable to the other embodiments of FIGS. 5-7.

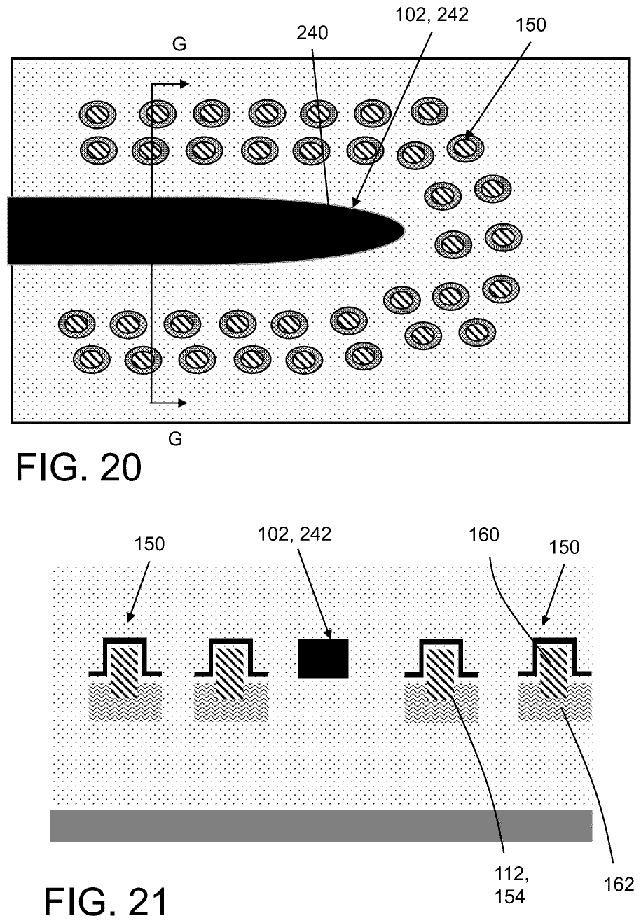

FIG. 20 shows a schematic top-down view and FIG. 21 shows a cross-sectional view along view line G-G in FIG. 19 of another embodiment of the disclosure. FIGS. 20-21 show an embodiment in which photonic component 102 includes a tapered end 240 of a waveguide 242, and guard elements 150 surround tapered end 240 in a U-shaped configuration. Here, guard elements 150 surround tapered end 240 and prevent radiation of optical signals in all directions. As shown in FIG. 21, waveguide 242 includes silicon nitride and may be located above active semiconductor layer 154; however, this is not necessary in all cases. While FIGS. 20-21 are shown with the germanium body 160 and silicon element 162 embodiment of guard elements 150, the teachings are equally applicable to the other embodiments of FIGS. 5-7.

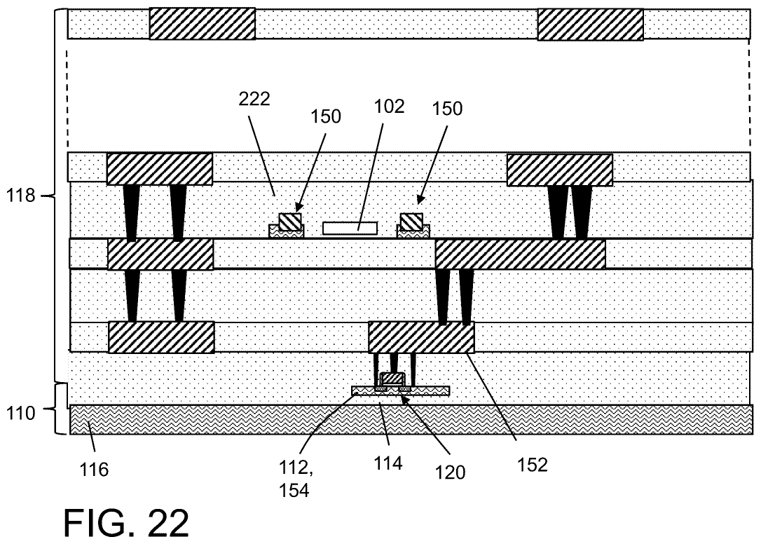

FIG. 22 shows a cross-sectional view of another embodiment in which guard elements 150 are positioned in a BEOL layer 222 in dielectric stack of materials 118. Guard elements 150 can be in any layer of dielectric stack of materials 118 in which a photonic component 102 exists.

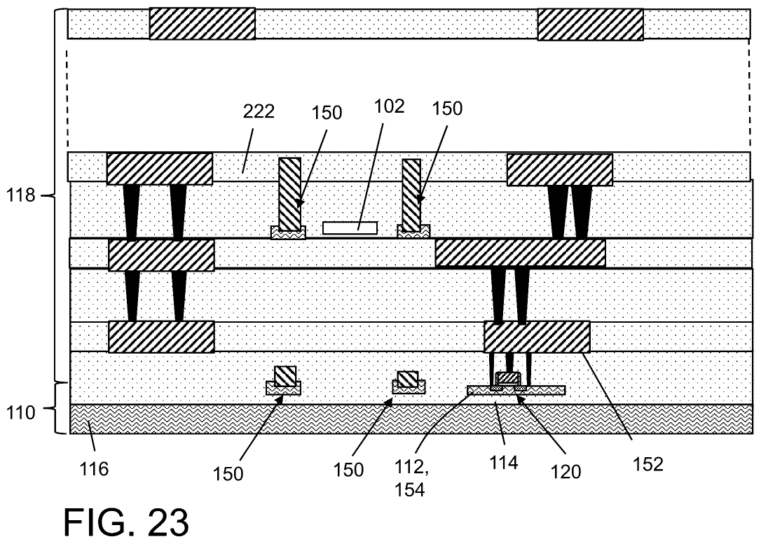

FIG. 23 shows a cross-sectional view of another embodiment in which guard elements 150 are positioned in both active semiconductor layer 154 and a BEOL layer(s) 222 in dielectric stack of materials 118. Guard elements 150 can extend into and/or through any number of layers of dielectric stack of materials 118. Photonic component 102 can exist in any layer.

A method according to embodiments of the disclosure may include forming photonic component 102 over or on semiconductor substrate 110. This process may include any now known or later developed fabrication processes appropriate for the photonic component(s) 102 to be formed. For example, for photodetector 122 (FIGS. 1-2), the process may include forming germanium region 138 between n-type region 130 and p-type region 132 where n-type and p-type regions are in semiconductor substrate 110. The photonic component 102 formation processes may use any now known or later developed semiconductor fabrication techniques, e.g., depositing material layers, doping, patterning using photolithography and etching, among others.

The process may also include forming discrete optical guard elements 150 in proximity to photonic component(s) 102. Guard elements 150 are composed of a light absorbing material and are in proximity to photonic component 102. In certain embodiments, forming guard elements 150 adjacent photonic component(s) 102 includes forming a metamaterial including at least one of silicon and germanium. Guard elements 150 may be arranged in a manner to mimic an outer periphery of at least a portion of photonic component 102. In certain embodiments, forming guard elements 150 includes forming at least one of: germanium body 160 positioned at least partially in silicon element 162, silicon body 180, and polysilicon body 186 over silicon body 180. Other light absorbing materials may also be used.

In certain embodiments, guard elements 150 includes at least a portion in active semiconductor layer 154. In certain embodiments, guard elements 150 may be entirely below first metal layer 152. In other embodiments, guard elements 150 may be positioned in a BEOL layer in proximity to photonic component 102, see FIG. 21. For the germanium body 160 with silicon element 162 embodiment, forming guard elements 150 may include forming germanium body 160 positioned at least partially in silicon element 162 in active semiconductor layer 154 of semiconductor substrate 110 adjacent photonic component 102. Here, forming germanium region 138 and germanium body 160 may occur simultaneously. A trench may be formed in silicon element 162 and germanium body 160 may be formed therein, e.g., by epitaxy. Silicon element 162 and silicon body 180 may or may not be in active semiconductor layer 154 of semiconductor substrate 110 adjacent photonic component(s) 102. Silicon body 180 may have a high dopant concentration in active semiconductor layer 154, and polysilicon body 186 may have a high dopant concentration over silicon body 180.

As shown in FIG. 1, guard elements 150 may be arranged in one or more rows. As shown in the various embodiments, guard elements 150 may be aside an outer periphery of at least a portion of photonic component(s) 102, and in some cases may substantially surround photonic component(s) 102. Guard elements 150 forming processes may use any now known or later developed semiconductor fabrication techniques, e.g., depositing material layers, doping, patterning using photolithography and etching, among others.

Embodiments of the disclosure provide various technical and commercial advantages, examples of which are discussed herein. Guard elements 150 reduce optical noise and provide performance improvements for functional components and circuits (e.g., dark current reduction, scattering loss reduction). The guard elements are fully compatible with current semiconductor process flows and do not require additional layers and/or process steps. The guard elements can be placed in any area where stray optical signals (light scattering) are anticipated, such as but not limited to in proximity to optical input/outputs such as an edge coupler, laser cavity/coupler, V-groove/IOSMF, grating coupler, or chip edges; in proximity to waveguide bends, couplers, splitters, spiral absorbers, etc.; and/or surrounding sensitive photonic components such as photodetectors and/or optical modulators.

The method as described above is used in the fabrication of photonic integrated circuit chips. The resulting integrated circuit chips can be distributed by the fabricator in raw wafer form (that is, as a single wafer that has multiple unpackaged chips), as a bare die, or in a packaged form. In the latter case the chip is mounted in a single chip package (such as a plastic carrier, with leads that are affixed to a motherboard or other higher-level carrier) or in a multichip package (such as a ceramic carrier that has either or both surface interconnections or buried interconnections). In any case the chip is then integrated with other chips, discrete circuit elements, and/or other signal processing devices as part of either (a) an intermediate product, such as a motherboard, or (b) an end product. The end product can be any product that includes integrated circuit chips, ranging from toys and other low-end applications to advanced computer products having a display, a keyboard or other input device, and a central processor.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about”, “approximately” and “substantially”, are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

What is claimed is:

1. A photonic integrated circuit (PIC) structure, comprising:
a photonic component on a semiconductor substrate; and
a plurality of discrete optical guard elements each composed of a light absorbing material and in proximity to the photonic component.

2. The PIC structure of claim 1, wherein the plurality of discrete optical guard elements each include a metamaterial including at least one of silicon and germanium.

3. The PIC structure of claim 1, wherein the plurality of discrete optical guard elements includes at least one of: a germanium body positioned at least partially in a silicon element, a silicon body having a high dopant concentration, and a polysilicon body having a high dopant concentration over a silicon body.

4. The PIC structure of claim 1, wherein the plurality of discrete optical guard elements each have a horizontal cross-sectional shape that is one of: circular, oval, rectangular, and square.

5. The PIC structure of claim 1, wherein the plurality of discrete optical guard elements have more than one horizontal cross-sectional shape.

6. The PIC structure of claim 1, wherein the plurality of discrete optical guard elements are arranged in a manner to mimic an outer periphery of at least a portion of the photonic component.

7. The PIC structure of claim 1, wherein the plurality of discrete optical guard elements are arranged in at least two rows.

8. The PIC structure of claim 1, wherein the plurality of discrete optical guard elements are non-uniformly spaced along an outer periphery of at least a portion of the photonic component.

9. The PIC structure of claim 1, further comprising an optical waveguide extending through a gap in the plurality of discrete optical guard elements, the optical waveguide in optical communication with the photonic component.

10. The PIC structure of claim 1, further comprising a dielectric layer surrounding the plurality of discrete optical guard elements.

11. The PIC structure of claim 1, wherein the photonic component includes an optical absorber including a spiral waveguide body and a linear input waveguide coupled to the spiral waveguide body, and wherein the plurality of discrete optical guard elements surrounds the spiral waveguide body and the linear input waveguide.

12. The PIC structure of claim 1, wherein the photonic component includes a tapered end of a waveguide, and the plurality of discrete optical guard elements surround the tapered end in a U-shaped configuration.

13. The PIC structure of claim 1, wherein the plurality of discrete optical guard elements are arranged in an L-shape having a first plurality of elements adjacent a portion of the photonic component, and a second plurality of elements adjacent a waveguide in optical communication with the photonic component.

14. A photonic integrated circuit (PIC) structure, comprising:
a photonic component on a semiconductor substrate; and
a plurality of discrete optical guard elements composed of a light absorbing material and in proximity to the photonic component,
wherein the plurality of discrete optical guard elements each include a metamaterial including at least one of silicon and germanium, and
wherein the plurality of discrete optical guard elements are arranged in a manner to mimic an outer periphery of at least a portion of the photonic component.

15. The PIC structure of claim 14, wherein the plurality of discrete optical guard elements are arranged in at least two rows.

16. The PIC structure of claim 14, wherein the plurality of discrete optical guard elements are non-uniformly spaced along an outer periphery of at least a portion of the photonic component.

17. A method, comprising:
forming a photonic component on a semiconductor substrate; and
forming a plurality of discrete optical guard elements composed of a light absorbing material and in proximity to the photonic component.

18. The method of claim 17, wherein forming each of the plurality of discrete optical guard elements includes forming a germanium body positioned at least partially in a silicon element.

19. The method of claim 17, wherein forming each of the plurality of discrete optical guard elements includes forming a metamaterial including at least one of silicon and germanium.

20. The method of claim 17, wherein forming the plurality of discrete optical guard elements includes arranging the plurality of discrete optical guard elements in a manner to mimic an outer periphery of at least a portion of the photonic component.
